(19) United States
(12) Patent Application Publication
(10) Pub. No.: US 2009/0260678 A1
(43) Pub. Date: Oct. 22, 2009

(54) GLASS SUBSTRATE BEARING AN ELECTRODE

(75) Inventor: Gaeetan DI STEFANO, Jumet (BE)

Correspondence Address: OBLON, SPIVAK, MCCLELLAND MAIER & NEUSTADT, L.L.P., 1940 DUKE STREET, ALEXANDRIA, VA, 22314, US

(73) Assignee: AGC Flat Glass Europe S.A., Bruxelles (BE)

(21) Appl. No.: 12/423,977

(22) Filed: Apr. 15, 2009

(30) Foreign Application Priority Data
Apr. 16, 2008 (EP) 08 103 576.8

(51) Int. Cl. H01L 31/04

(52) U.S. Cl. 136/252

(57) ABSTRACT

The invention relates to a glass substrate bearing at least one electrode in the form of a thin layer. A barrier covering 2 for species migrating from the glass comprising at least one layer based on a mixed oxide of zinc and at least one other element containing at least 10% zinc is arranged between the substrate 1 and the electrode 3. The invention is applied in particular to electronic devices such as chalcopyrite-based photovoltaic cells.

The present invention relates to a glass substrate bearing at least one electrode in the form of a thin layer for an electronic device such as a photovoltaic cell, and also to an electronic device comprising such a substrate bearing at least one electrode.

The electrode of an electronic device is intended to distribute or capture an electric current. To enable said device to operate correctly, it is essential that the electrode has an electrical resistance that is as low as possible, while taking into consideration other essential requirements for construction or operation of the device, in order to reduce electric losses as far as possible.

There are various electronic devices that use a glass substrate bearing an electrode. Examples are in particular intelligent glazing such as electrochromic glazing, devices using illumination based on LEDs (light-emitting diodes) or OLEDs (organic light-emitting diodes), into which the current is directed via electrodes arranged on glass etc. The invention shall be described more particularly with reference to photovoltaic cells, also called solar cells, for the conversion of solar light into electricity. There has been rapid development in these electronic devices particularly in recent years because of the search for alternative sources of energy to energy from fossil fuels.

Various technologies have been developed to replace the traditional silicon crystal-based photovoltaic cells and in particular chalcopyrite-based cells such as so-called CIS solar cells (based on copper and indium selenide and/or sulphide such as CuInSe₂, CuInS₂) or CIGS solar cells (based on copper, indium and gallium selenide and/or sulphide), or solar cells based on copper, indium and aluminium selenide and/or sulphide, or so-called CZTS solar cells (based on copper, zinc and tin selenide and/or sulphide such as Cu₂ZnSnS₄ or Cu₂ZnSnSe₄).

During the production of some electronic devices such as solar cells and in particular CIS, CZTS or CIGS type solar cells (including cells, in which aluminium replaces gallium), the substrate bearing the electrode can be subjected to a high-temperature thermal treatment, e.g. at a temperature above 500° C., even above 550° C. (e.g. 550-600° C.), for about 5 to 30 minutes in one or more steps in a generally selenium- or sulphur-based atmosphere, or selenium then sulphur-based atmosphere, to cause layers of Cu and In deposited on the electrode to react with the Se and/or S. When a glass substrate, in particular a conventional soda-lime-silica glass, is subjected to these elevated temperatures, a diffusion of alkaline ions such as sodium ions towards the surface of the substrate is produced. These ions cause contamination of the electrode arranged on the substrate in an uncontrollable manner. This contamination can undesirably reduce the conductivity of the electrode, at least from a certain level. It also has an adverse effect on the interfaces by reducing adhesion between the layers, in particular the adhesion between the electrode and the functional layer, e.g. based on chalcopyrite. It can also have an adverse effect on the functional element of the solar cell, e.g. the chalcopyrite-based layer. In fact, at a low concentration sodium has a positive effect on the functional element, but the effect quickly becomes negative if the concentration increases beyond a certain level.

To reduce this problem it has been proposed to deposit a barrier layer on the substrate before depositing the electrode to reduce the migration of sodium ions.

International Patent Application WO 02/065554 A1, filed by Saint-Gobain Glass France, describes a CIS type solar cell formed on a glass sheet bearing a molybdenum electrode. To form a barrier against the migration of alkaline ions outside the glass substrate and prevent degradation of the molybdenum electrode, this document proposes to arrange a barrier layer formed from silicon nitride, oxynitride or oxide or aluminium nitride or oxynitride on the substrate. Since molybdenum is costly, this document also proposes to substitute part of the Mo of the electrode by adding another conductive layer.

European Patent Application EP 1 833 096 A1, filed by Showa Shell Sekiyu Kabushiki Kaisha Minato-ku, describes a CIS or CIGS type solar cell that has a Mo electrode deposited on a glass substrate. This document proposes to deposit a barrier layer of SiO₂ or SiOx between the substrate and the electrode to form a barrier against the diffusion of alkaline ions coming from the glass.

The International Patent Application WO 2007/106250 A2, filed by Guardian Industries Corp., proposes to arrange a barrier layer of silicon nitride between the glass substrate and the molybdenum electrode of a CIS or CIGS type solar cell in order to reduce the migration of sodium coming from the glass.

These proposals enable the problem to be reduced but are not completely satisfactory and they pose some difficulties in implementation, in particular with respect to yields and rate of deposition. Moreover, some problems of poor adhesion can arise at the interfaces. Si₃N₄ or Si₃NxOy, possibly doped with aluminium, for example, forms a layer that has high residual internal stresses, and this causes adhesion problems. The formation of holes, so-called pinholes, in the stack has also been observed at times.

The invention relates to a glass substrate bearing at least one electrode in the form of a thin layer for an electronic device, characterised in that a barrier covering comprising at least one layer based on a mixed oxide of zinc and at least one other element containing at least 10% by weight of zinc is arranged between the substrate and the electrode.

### BRIEF DESCRIPTION OF THE DRAWINGS

FIG. 1 shows a cross-section of a glass sheet bearing an electrode according to the invention;

FIG. 2 shows the graph of an XPS analysis conducted on the glass sheet bearing the electrode of FIG. 1 before thermal treatment; and

FIG. 3 shows the graph of an XPS analysis conducted on the glass sheet bearing the electrode of FIG. 1 after thermal treatment.

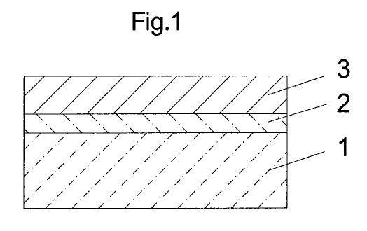

In FIG. 1 reference 1 relates to the glass substrate, reference 2 relates to the barrier covering in its entirety and reference 3 relates to the electrode.

Barrier covering is understood to mean a covering that forms a barrier to migrating species coming from the glass substrate, such as oxygen and alkaline ions, by slowing down their migration.

Expressions similar to “mixed oxide of zinc and another element containing at least 10% zinc and at least 10% of another element” used in the present description mean that there is at least 10% by weight of zinc and at least 10% by weight of the other element in the mixed oxide in relation to the total weight of zinc and the other element in the mixed oxide. The same applies to the different percentages of zinc and the other element in the mixed oxide given below, as well as to values other than 10% given here for purposes of illustration.

Said barrier covering and the electrode are preferably deposited by reduced-pressure cathodic sputtering that is advantageously improved by means of a magnetic field in the magnetron device. The magnetron device can be a horizontal device where the glass substrate moves horizontally under the adequate sputtering targets. Advantageously, one can use a vertical device where the glass substrate moves in substantially vertical position in front of sputtering targets. A vertical device has the advantage of reducing the number of defects of the type “pinholes” coming from residues falling on glass inside the magnetron device.

It has been found that such a layer based on mixed oxide of zinc and another element forms an effective barrier to greatly reduce the migration of alkaline ions coming from the substrate when this is heated, and that it has a very favourable effect on the conductivity of the electrode after thermal treatment. The thickness of the electrode can also be reduced to obtain the same conductance value, which is advantageous in terms of production costs. Since the material of the electrode is very costly in some application cases, e.g. molybdenum for CIS, CZTS or CIGS solar cells, the invention provides a clear advantage. Besides the advantage of cost, the reduction in thickness of the electrode also has the advantage of reducing the risk of so-called pinholes forming in the layer that allow ions such as sodium ions to pass through, and also of reducing the intensity of internal stresses, which is an advantage with respect to the adhesion of the electrode to the substrate.

Moreover, a layer based on mixed oxide of zinc and another element is easier to deposit without defects and provides a better magnetron deposition efficiency than the known barrier layers of silicon nitride or silicon oxides. Control of the deposition process is easier and enables substantial savings in a commercial series production.

Moreover, it has been found that this barrier layer based on a mixed oxide of zinc and another element also promotes very favourable adhesion of the electrode in relation to the glass substrate.

It is surprising that the invention provides these advantageous results, in particular in the application case of CIS, CZTS or CIGS type solar cells. In fact, elements—Zn and the other element—to which the functional layer is more sensitive than to the silicon of the glass, are thus introduced into the structure. If these metals reach the function layer, there is a risk of it being degraded in an adverse manner. The problem does not arise with Si₃N₄ or SiO₂ barriers, which are elements close to glass and based on silicon like glass. It has been found that the functional layer is not contaminated at all by these metals. The mixed oxide of zinc and the other element is probably so thermally stable that there is no diffusion of zinc and the other element through the electrode.

The glass substrate can be formed from any appropriate vitreous material containing species capable of migrating under the effect of an external phenomenon such as an increase in temperature. According to a preferred embodiment of the invention, the substrate is formed from a glass with a high fusion point, such as a glass with a strain point in the order of 570-590° C. This type of glass allows thermal treatments to be conducted at very high temperature that are beneficial for obtaining quality functional layers for solar cells of the type CIS, CZTS or CIGS. This can concern a glass of the SiO₂—Al₂O₃-alkaline oxides-alkaline earth oxides system. Examples that may be cited are e.g. the glass sold under the designation PD200 by Asahi Glass Company adapted to the formation of transmission screens or the glass sold under the designation PV200 by the same company that is especially suitable for use as substrate in the formation of photovoltaic cells.

According to another preferred embodiment, the glass substrate is formed from a conventional soda-lime-silica glass having a base composition with the following proportions: 60% to 75% SiO₂, 10% to 20% Na₂O, 0% to 16% CaO, 0% to 10% K₂O, 0% to 10% MgO, 0% to 5% Al₂O₃ and 0% to 2% BaO. Different colouring agents can be added to this base composition. The glass substrate is preferably transparent.

The electrode is formed from a metal that is resistant to the elevated production temperatures of the electronic device. In the case of CIS, CZTS or CIGS type solar cells, the metal of the electrode must be resistant to action from selenium and/or sulphur. Moreover, it must not readily form an alloy with copper or indium. For example, it can be formed from tungsten, tantalum or niobium. The electrode is preferably molybdenum-based. This is the metal currently used to produce the base electrode for a chalcopyrite-based photovoltaic solar cell of type CIS, CZTS or CIGS because of its properties suitable for this use. This refractory metal easily withstands the high-temperature thermal treatment necessary for the production of the cell and has good resistance to the selenide and/or sulphide used to form the functional layer of the cell that is in contact with the electrode carried by the glass substrate. It has a low reactivity with respect thereto.

The electrode in layer form can be a uniform layer over the entire surface of the glass substrate or extend over only a part of this surface. In general, the electrode layer is cut out according to a specific design adapted to the electronic device, which it will form part of in the finished product. It is generally cut out by means of a laser beam. Its thickness is generally in the range of between 50 and 1500 nm. The layer forming the electrode preferably has a total thickness of less than 1000 nm, advantageously less than 800 nm, and ideally less than 600 nm. In the case of a CIS, CZTS or CIGS type solar cell, its thickness is advantageously in the range of between 250 and 520 nm. The electrical resistance can be in the order of 10 to 15Ω/□ (ohms per square), even in the order of 5 to 8Ω/□, but this type of electronic device generally requires the electrical resistance of the electrode as far as possible to be lower than 5 ohms/□ (ohms per square) or less than 2 or 3Ω/□, and even preferably less than 1 ohm/o when the device is in operating order, i.e. the electrode has possibly had to undergo a high-temperature thermal treatment subsequent to the production of the cell. The surface electrical resistance of a very fine layer deposited onto an insulating substrate is generally expressed in “ohms per square”, the value of the resistance does not depend on the dimension of the square. For reference purposes, it is considered in the present description that this surface resistance value must be obtained after a thermal treatment of the substrate bearing the electrode at 500° C. for 30 minutes, wherein this electrode is protected from the surrounding atmosphere during the thermal treatment to prevent surface oxidation. The electrical resistance of the electrode is preferably less than 2 ohms/□, advantageously less than 0.8 ohms/□, and more preferred equal to or less than 0.6 ohms/□, i.e. after said thermal treatment. As a result of the invention, this low resistance can be obtained after high-temperature thermal treatment with a lower thickness of the electrode than in structures without the barrier layer, in particular with a thickness of less than 510 nm in the case of a molybdenum electrode. Because molybdenum is a very costly material, the advantage of a reduction in thickness is obvious. The invention allows this reduction in thickness without having to complicate the production process and add additional conductive materials, which are sources of defects, as proposed in WO 02/065554 A1, which adds additional conductive layers of a material other than molybdenum.

The electrode in layer form can be subdivided in its thickness into a multilayer deposit comprising at least two layers formed by cathodic sputtering in a neutral atmosphere from the same cathode but in different deposition conditions (power and/or pressure). It is preferably subdivided into at least three layers, e.g. into five layers. As a result, a sequence of less dense layers and denser layers can be obtained. It has been found that the adhesion to the glass substrate could thus be improved, in particular after thermal treatment, and a good electrical contact to the interface with the functional layer obtained.

The mixed oxide of the barrier covering comprises zinc and at least one other element. Said other element is preferably selected from the following elements: Sn, Ti, Ta, Zr, Nb, Ga, Bi, Al and a mixture thereof. The oxides of these elements mixed with zinc oxide have a favourable effect for the formation of an effective barrier to species migrating from the glass.

The barrier covering preferably consists of a stack of at least two layers of different compositions. Multiplication of the interfaces improves the barrier effect.

Said other element is preferably present to an amount of at least 4% by weight, e.g. 5% by weight. Said other element is advantageously present to an amount of at least 10% by weight, preferably at least 12% by weight.

The mixed oxide of the barrier covering can be advantageously formed from a mixed oxide of zinc and aluminium to an amount of at least 4% by weight of aluminium, e.g. 5% (i.e. about 12 atom %). It can also preferably contain at least 10%, advantageously at least 12%, by weight of aluminium and forming so a very effective barrier to species migrating from the glass. This mixed oxide can be formed from a cathode of a zinc-aluminium alloy sputtered into a reactive atmosphere of oxygen and argon. It can also be obtained from a mixed oxide ceramic cathode sputtered in a neutral or lightly oxidising atmosphere.

The mixed oxide of the barrier covering can also be advantageously formed from a mixed oxide of zinc and titanium or a mixed oxide of zinc, titanium and aluminium.

The mixed oxide of zinc and another element preferably comprises at least 20% zinc, and advantageously at least 30%.

It is preferred if said other element is tin and the zinc-tin mixed oxide contains at least 20% tin. It was found that the zinc-tin mixed oxide formed a particularly effective barrier covering.

The barrier covering can be formed from a single layer of an adequate thickness based on a zinc-tin mixed oxide that advantageously has a composition close to Zn₂SnO₄. The barrier covering preferably comprises a stack of at least two layers based on zinc-tin mixed oxide of different compositions. Advantageously, a mixed zinc-tin oxide layer formed by reactive cathodic sputtering in the presence of oxygen from a cathode of a zinc-tin alloy of approximately 90% by weight of zinc and 10% by weight of tin is sandwiched between two zinc-tin mixed oxide-based layers with a composition close to Zn₂SnO₄. It was found that this particular arrangement benefits the increase in conductivity of the electrode after high-temperature thermal treatment in relation to a barrier covering formed from a single mixed oxide layer. The reason for this increase is not really known, but it is thought that the creation of an interface in the zinc-tin mixed oxide layer with the formation of more amorphous layer sections at the interfaces that improve the barrier effect with respect to migrating ions plays a particular role.

The zinc-tin mixed oxide-based layer can contain at least 30% tin. At least one zinc-tin mixed oxide-based layer preferably comprises at least 40% tin and at least 40% zinc. Advantageously, the zinc-tin mixed oxide is formed by reactive cathodic sputtering in the presence of oxygen from a cathode of a zinc-tin alloy of 52% by weight of zinc and 48% by weight of tin in order to obtain an oxide with a composition that is as close as possible to zinc stannate Zn₂SnO₄ in the layer. We have discovered that the best blocking effect against the migration of alkaline ions is achieved if the composition is close to this particular composition.

The total thickness of the barrier covering must be sufficient to form an effective barrier and to block the migration of alkaline ions from the glass substrate to the electrode and even to the functional layer deposited on the electrode. A thickness of the barrier of at least 50 nm has proved necessary when the thermal treatment is conducted at over 400° C. for duration of more than 5 minutes. The thickness must not be unnecessarily excessive so as not to burden the production costs. A thickness greater than 500 nm is not justifiable and a thickness smaller than 200 nm has proved sufficient for the majority of application cases. The barrier covering preferably has a total thickness in the range of between 80 and 500 nm, advantageously between 80 and 200 and more preferred between 100 and 150 nm. A thickness between 120 and 140 nm, for example, has been found to be a good compromise for the formation of a CIS, CZTS or CIGS type photovoltaic solar cell.

A good adhesion of the electrode to the substrate is an important factor because if the electrode is detached from the substrate, the electronic device becomes defective. In order to qualify the adhesion of the electrode to the substrate, we have defined an adhesion test as follows:

A circular flat head made of Teflon covered by a cotton fabric is drawn over the layer with a constant and integrated load. The surface of the layer covered by the friction of fabric is of 2.81 cm² and the load applied is of 3,850 g. The abrasion of the cotton on the covered surface will damage (or remove) the layer after a certain number of cycles. The cotton must be kept moist with deionised water for the whole duration of the test. The speed must be adjusted to between 60 and 90 complete oscillations (back and forth) per minute. The test is used to define the threshold where the layer becomes discoloured and/or the threshold where scratches appear on the layer. The sample is observed before an artificial background to determine whether any discolouration or scratches can be seen on the sample. No detachment must be identified for the test to succeed.

The electrode is preferably not detached from the substrate after having undergone a thermal treatment at 500° C. for 30 minutes when it is subjected to the above-described adhesion test.

The adhesion is also an important factor for the interface between the functional layer and the electrode. If sodium were to migrate to this interface, there would be a risk of detachment of the functional layer from the electrode.

The invention also applies to an electronic device comprising a glass substrate bearing an electrode as described above.

This electronic device is preferably a chalcopyrite-based photovoltaic solar cell comprising a layer of selenide and/or sulphide of copper and indium or tin possibly with gallium or aluminium or zinc deposited onto the electrode, preferably made of molybdenum.

The invention shall now be described in more detail with reference to the following examples and the attached drawings.

### EXAMPLES

### Comparative Example

A sheet of conventional soda-lime glass with a thickness of 2.1 mm was inserted into a magnetron-type deposition device. In this device an electrode in the form of a 500 nm thick layer of Mo was deposited at a pressure of 0.4 Pa and with a power of 1.14 W/cm². The resistance of the electrode amounts to 0.6Ω/□. In order to test this structure for comparison purposes, it was subjected to a thermal treatment similar to that conducted during the production of a CIS type solar cell. It should be noted that the Mo electrode was not protected from the outside atmosphere during the thermal treatment. The molybdenum layer is thus oxidised on the outside surface, which does not occur during real production of the solar cell. The thermal treatment was conducted at 500° C. for 30 minutes in a non-controlled atmosphere, i.e. in air.

The electrical resistance of the molybdenum electrode was measured after thermal treatment and a value ranging from 3.2 to 12Ω/□, depending on the location on the surface of the electrode, was observed. This value varies depending on location because of the oxidation of the molybdenum during the thermal treatment.

### Example 1

The same test as in the above comparative example was reproduced, except that a 130 nm thick barrier covering formed from a zinc-tin mixed oxide according to the invention was firstly deposited on the glass before deposition of the electrode. This layer was deposited from a cathode of a zinc-tin alloy with 52% by weight of zinc and 48% by weight of tin to form a layer of Zn₂SnO₄ on the glass.

After thermal treatment as in the comparative example, an electrical resistance ranging from 2.5 to 3.2Ω/□, depending on the location on the surface of the electrode, was measured. This value varied according to location because the electrode was oxidised during the thermal treatment because it was not protected from the oxidising atmosphere. It was found that the maximum value was appreciably lower than for the above comparative example. The presence of the barrier covering according to the invention has therefore noticeably protected the electrode from species migrating from the glass during the thermal treatment, since the electrical resistance had increased substantially less than in the comparative example.

### Example 2

A conventional soda-lime glass sheet 1 with a thickness of 2.1 nm was inserted into a magnetron-type deposition device. At a total pressure of 0.4 Pa and in an atmosphere of a mixture of oxygen and argon at a rate of 80% O₂ a 130 nm layer of zinc-tin mixed oxide 2 was deposited on the glass from a cathode of a zinc-tin alloy with 52% by weight of zinc and 48% by weight of tin. A molybdenum electrode layer 3 with a total thickness of 500 nm was then deposited from a molybdenum target in a neutral argon atmosphere. This molybdenum electrode was subdivided into 5 layers, the thickness of which was respectively 40/190/40/190/40 nm under conditions of total pressure and power respectively identified by A/C/A/C/A, wherein these letters correspond to the conditions given in the following Table 1.

TABLE 1

| | Power | Pressure |
|---|---|---|
| Condition | [Wcm²] | [Pa] |
| A | 0.63 | 0.66 |
| B | 1.56 | 0.4 |
| C | 2.08 | 0.4 |
| D | 1.15 | 0.4 |

To test this structure, it was subjected to a thermal treatment similar to that conducted during the production of a CIS type solar cell. To protect this structure from the outside atmosphere during the thermal treatment, it was covered by a 130 nm layer of zinc stannate Zn₂SnO₄ for the purposes of the test. The thermal treatment was conducted at 500° C. for 30 minutes in a non-controlled atmosphere, i.e. in air.

The electrical resistance of the molybdenum electrode was measured before and after the thermal treatment. Before thermal treatment the value 0.29Ω/□ was observed. After thermal treatment the value 0.36Ω/□ was observed.

It was therefore found that the electrical resistance practically did not increase following the thermal treatment and that its final value for a 500 nm electrode is completely adequate for the formation of a CIS, CZTS or CIGS type solar cell.

Moreover, dynamic XPS and SIMS analyses were conducted before and after thermal treatment, which very clearly confirmed that the mixed oxide layer according to the invention formed a very effective barrier to the migration of sodium from the glass.

In an XPS analysis, the sample is irradiated by monochromatic X-rays that cause ionisation of its atoms by photoelectric action. The kinetic energy of these photoelectrons is measured, and this enables the binding energy and therefore the nature of the atom to be deduced.

In a dynamic SIMS analysis, the surface of the sample to be analysed is bombarded with an ion beam. The sample is then sputtered and a portion of the sputtered material is ionised. These secondary ions are then accelerated towards a mass spectrometer that will enable the base or isotopic composition of the surface of the sample to be measured.

These analyses additionally show that the zinc and tin of the mixed oxide did not migrate through the molybdenum electrode at all, which means that these metals would not contaminate the functional layer of the solar cell.

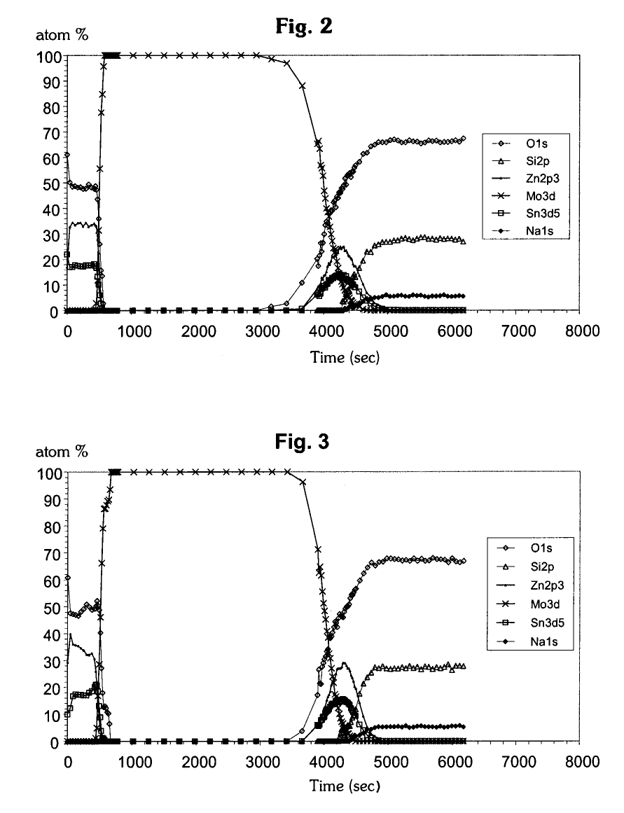

FIG. 2 shows the graph obtained following the XPS analysis of the sample according to Example 2 before thermal treatment. FIG. 3 shows the graph obtained following the XPS analysis of the sample according to Example 2 after thermal treatment. The irradiation time in seconds is shown on the abscissa and the atomic percentage of the elements is shown on the ordinates. Looking at FIG. 3 in comparison to FIG. 2, it is evident that sodium has not migrated into the electrode 3 during the thermal treatment and has remained blocked by the barrier layer 2 of zinc-tin mixed oxide. It is also evident that the zinc and tin have not migrated through the electrode layer 3. In fact, it is evident that the percentage of sodium (Na1S) drops to zero in the zone where the zinc (Zn2p3) and tin (Sn3d5) have elevated values. It is also evident that in the range where molybdenum (Mo3d) is at maximum, the sodium, zinc and tin are at zero.

In addition, the coated substrate was subjected to an adhesion test, as described above. No detachment or discolouration of the layer was observed.

### Examples 3 to 10

Example 1 was repeated with modification of certain parameters. The structures and conditions of deposition of the electrode are given in Table 2 below.

In Examples 4, 6 and 7, the molybdenum electrode was subdivided into 5 layers, the thicknesses and conditions of deposition of which are given in Table 2, wherein the letters A, B, C and D correspond to the deposition conditions given in the above Table 1. In Example 7, the barrier covering was subdivided into three zinc-tin mixed oxide layers: a layer with a lower content of tin was enclosed between two layers of zinc stannate Zn₂SnO₄. In the “structure” column in this Table 2, the symbol ZSO₅ represents a zinc-tin mixed oxide obtained by cathodic sputtering in an oxidising atmosphere from a metal target of a ZnSn alloy with 52% by weight of Zn and 48% by weight of Sn, and the symbol ZSO₉ represents a zinc-tin mixed oxide obtained by cathodic sputtering in an oxidising atmosphere from a metal target of a ZnSn alloy with 90% by weight of Zn and 10% by weight of Sn.

The samples of these examples were subjected to a thermal treatment at 500° C. for 30 minutes in a non-controlled atmosphere, i.e. in air, as in the previous examples. It should again be noted that the molybdenum electrodes were not covered and were therefore not protected from oxidation during the thermal treatment.

The electrical resistances of the electrodes were measured before and after thermal treatment. The measured values are given in Table 2. It should be noted that these values are variable according to location because of the oxidation of the molybdenum during the thermal treatment, and therefore the table indicates the minimum and maximum measured.

TABLE 2

| | Barrier Covering | | Mo Electrode Layer | | Resistance (Ω/□) | |
|---|---|---|---|---|---|---|
| Ex. | Thickness (nm) | Structure | Thickness (nm) | Condition | Before treat. | After treat. |
| 3 | 130 | ZSO5 | 500 | B | 0.38 | 1.00 to 1.21 |
| 4 | 130 | ZSO5 | 40/190/40/190/40 | A/B/A/B/A | 0.45 | 1.76 to 1.93 |
| 5 | 130 | ZSO5 | 500 | C | 0.39 | 1.02 to 1.12 |
| 6 | 130 | ZSO5 | 40/190/40/190/40 | A/C/A/C/A | 0.44 | 1.17 to 1.54 |
| 7 | 50/30/50 | ZSO5/ZSO9/ZSO5 | 40/190/40/190/40 | A/C/A/C/A | 0.30 | 0.67 to 0.84 |
| 8 | 80 | ZSO5 | 500 | D | 0.55 | 2.26 to 3.05 |
| 9 | 130 | ZSO5 | 500 | D | 0.61 | 1.43 to 1.81 |
| 10 | 180 | ZSO5 | 500 | D | 0.57 | 1.71 to 2.27 |

Example 7 shows that it is advantageous to subdivide the barrier covering. Examples 8 to 10 show that, for the given structure and with every other parameter remaining constant, the thickness of 130 nm of the barrier covering is sufficient and a thickness of 180 nm is superfluous.

### Examples 11 and 12

A conventional soda-lime glass sheet 1 with a thickness of 2.1 nm was inserted into a magnetron-type deposition device. At a total pressure of 0.4 Pa and in an atmosphere of a mixture of oxygen and argon at a rate of 80% O₂, a 130 nm layer of zinc-titanium mixed oxide 2 was deposited on the glass from a 432 by 127 mm planar cathode of a zinc-titanium alloy with 70% by weight of zinc and 30% by weight of titanium. A molybdenum electrode layer 3 was then deposited from a molybdenum target, having the same dimension as the zinc-titanium alloy cathode, in a neutral argon atmosphere at a pressure of 0.6 Pa and with a power of 3 kW. The thickness of the molybdenum electrode was 300 nm thick for example 11 and 500 nm thick for example 12.

To test this structure, it was subjected to a thermal treatment similar to that conducted during the production of a CIS type solar cell. To protect this structure from the outside atmosphere during the thermal treatment, it was covered by a 130 nm layer of zinc stannate Zn₂SnO₄ for the purposes of the test. The thermal treatment was conducted at 500° C. for 30 minutes in a non-controlled atmosphere, i.e. in air.

The electrical resistance of the molybdenum electrode was measured before and after the thermal treatment. Before thermal treatment the value 0.61Ω/□ was observed for example 11 and the value 0.35Ω/□ was observed for example 12. After thermal treatment the value 0.94Ω/□ was observed for example 11 and the value 0.51Ω/□ was observed for example 12.

It was therefore found that the electrical resistance evolved little following the thermal treatment and that its final value is lower than 1 Ohm/□, and even lower than 0.6 Ohm/□ for example 12, completely adequate for the formation of a CIS, CZTS or CIGS type solar cell.

As a variant of example 11, titanium was replaced by 12% by weight of aluminium in the zinc-titanium alloy cathode forming the mixed oxide layer 2, providing also an adequate substrate for the formation of a CIS, CZTS or CIGS type solar cell.

### Example 13

Example 11 was repeated except for the mixed oxide layer 2. In example 13, le layer 2 was subdivided into three films according to the following sequence: a first film of 50 nm of ZSO₅ (zinc-tin mixed oxide as in example 3), followed by a second film of 30 nm of a mixed oxide zinc-titanium ZnTiOx, having the same composition as in example 11, and by a third film of 50 nm of ZSO₅ (same as the first film). This example 13 was subjected to the same thermal treatment that in example 11 and the electrical resistance of the molybdenum electrode was measured before and after the thermal treatment. Before thermal treatment the value 0.58 Ohm/□ was observed. After thermal treatment the value 0.89 Ohm/□ was observed.

It was again found that the electrical resistance evolved little following the thermal treatment and that its final value is lower than 1 Ohm/□, completely adequate for the formation of a CIS, CZTS or CIGS type solar cell.

### Example 14

In example 14 the molybdenum electrode 3 was 330 nm thick and was subdivided into two films: a first film of 30 nm thick deposited at 0.4 Pa by powering the Mo cathode at 2.41 kW/cm², followed by a second film of 300 nm thick deposited at 0.6 Pa by powering the Mo cathode at 9.64 kW/cm².

The mixed oxide layer 2 according to example 14 was subdivided into three films in the same manner as in example 7.

This assembly was subjected to a thermal treatment in the same way as in example 1, the Mo electrode layer 3 being not protected from the atmosphere of the treatment, and the electrical resistance of the molybdenum electrode was measured before and after the thermal treatment. Before thermal treatment the value 0.58Ω/□ was observed. After thermal treatment, an electrical resistance ranging from 0.99 to 1.06Ω/□, depending on the location on the surface of the electrode, was measured.

For comparison purpose, a same Mo electrode layer was deposited directly on a glass sheet, without mixed oxide layer 2, in the same condition as in example 14 and the coated sheet was subjected to the same thermal treatment. Before thermal treatment the value 0.60Ω/□ was observed. After thermal treatment, an electrical resistance ranging from 5.89 to 11.02Ω/□, depending on the location on the surface of the electrode, was measured.

1. A glass substrate bearing at least one electrode in the form of a thin layer for an electronic device, which comprises:
a barrier covering comprising at least one layer based on a mixed oxide of zinc and at least one other element containing at least 10% zinc is arranged between the substrate and the electrode.

2. The glass substrate according to claim 1, wherein the electrode is molybdenum-based.

3. The glass substrate according to claim 1, wherein the thin layer forming the electrode has a total thickness of less than 100 nm.

4. The glass substrate according to claim 1, wherein the thin layer forming the electrode is subdivided into at least two layers formed by cathodic sputtering under different deposition conditions.

5. The glass substrate according to claim 1, wherein the electrical resistance of the electrode after undergoing a thermal treatment at 500° C. for 30 minutes and being protected from oxidation is less than 0.8 ohms/□.

6. The glass substrate according to claim 1, wherein said other element is selected from the group consisting of the following elements: Sn, Ti, Ta, Zr, Nb, Ga, Bi, Al and mixtures thereof.

7. The glass substrate according to claim 1, wherein the barrier covering comprises a stack of at least two layers of different compositions.

8. The glass substrate according to claim 1, wherein said other element is present up to an amount of at least 4% by weight.

9. The glass substrate according to claim 1, wherein said other element is tin, and in that the zinc-tin mixed oxide contains at least 20% tin.

10. The glass substrate according to claim 9, claim 1, wherein the barrier covering comprises a stack of at least two layers based on zinc-tin mixed oxide of different compositions.

11. The glass substrate according to claim 1, wherein at least one zinc-tin mixed oxide layer comprises at least 40% tin and at least 40% zinc.

12. The glass substrate according to claim 1, wherein the barrier covering has a total thickness in the range of 80 to 500 nm.

13. The glass substrate according to claim 1, wherein after having undergone a thermal treatment at 500° C. for 30 minutes, the electrode did not detach from the substrate when it was subjected to an adhesion test.

14. An electronic device having a glass substrate according to claim 1.

15. The electronic device according to claim 14, wherein the device is a photovoltaic solar cell.

16. The electronic device according to claim 14 wherein a layer based on a selenide and/or sulphide of copper and indium or of copper, zinc and tin is deposited on the electrode.

17. The glass substrate according to claim 1, wherein the electrical resistance of the electrode after undergoing a thermal treatment at 500° C. for 30 minutes and being protected from oxidation is equal to or less than 0.6 ohms/o.

18. The glass substrate according to claim 1, wherein said other element is selected from the group consisting of the following elements: Sn, Ti and Al.

19. The glass substrate according to claim 1, wherein the barrier covering has a total thickness in the range of 80 to 200 nm.

20. The glass substrate according to claim 19, wherein the barrier covering has a total thickness in the range of 100 to 150 nm.
